(19) United States
(12) Patent Application Publication
(10) Pub. No.: US 2025/0107034 A1
(43) Pub. Date: Mar. 27, 2025

(54) DEVICE FOR COOLING ELECTRONIC EQUIPMENT

(71) Applicant: Telefonaktiebolaget LM Ericsson (publ), Stockholm (SE)

(72) Inventors: Claudio D'INCÀ, Genova (IT); Sergio MOSTI, Genova (IT)

(21) Appl. No.: 18/832,159

(22) PCT Filed: Nov. 29, 2022
(86) PCT No.: PCT/EP2022/083718

§ 371 Date: Jul. 23, 2024

Related U.S. Application Data
(60) Provisional application No. 63/302,238, filed on Jan. 24, 2022.

(51) Int. Cl. H05K 7/20; F24F 7/007; F24F 13/12

(52) U.S. Cl. CPC H05K 7/20172; F24F 7/007; F24F 13/12

(57) ABSTRACT

A device for use with a fan. The device includes a shaft mounted at opposite ends via brackets to a housing of the fan, a curtain for blocking airflow through the fan in a closed position, the curtain being wound onto the shaft in an open position, a closing mechanism for unwinding the curtain to the closed position, and a locking mechanism for locking the curtain in the open position. In response to detection of malfunction of the fan the locking mechanism is released and the closing mechanism unwinds the curtain to the closed position.

### TECHNICAL FIELD

The present invention relates to a device for use with a fan for cooling electronic equipment.

### BACKGROUND

Computing devices as well as radio access nodes are thermally managed using fans that ensure proper airflow through the devices/nodes to help with heat dissipation. The fans are typically arranged in a form of fan trays and a single fan tray is typically formed with multiple fans. There are several reasons for using multiple fans:
1) Each fan contributes to the overall airflow (m³/s) and to the air pressure of the air blown through the device to be cooled down. In fact, the equipment provides resistance to the airflow itself so the fan must contribute to overall air pressure to ensure the air flows inside the equipment.
2) To avoid having a single point of failure multiple fans are also required by the ANSI/ETSI standards because in the case of a single fan failure the other fans can ensure the node survival until the fan tray is replaced with a new one.
3) To ensure uniform distribution of airflow in the requested area.

Fan redundancy is mandatory in order to have protection against a single fan failure. In this case the other fans must provide the airflow and right pressure to allow the system to survive in the worst case scenario of ambient temperature. An additional problem (in addition to the loss of a fan) is that the broken fan represents a breach of the thermal management system, the fan opening produces a leakage for the airflow and pressure generated by the other fans. When a fan breaks, the fan opening, which is located on the side where hot air is exhausted by other fans, causes hot air to flow into the device because the air pressure inside the device to be cooled is lower than the air pressure outside (caused by the fans working in the device). The leakage reduces pressure difference between inside and outside by allowing hot air to enter the device and, in consequence, less fresh (cold) air enters the device to be cooled. The hot air entering back into the system makes the situation even worse.

In order to overcome this problem higher power fans must be used. Over-dimensioning leads to more expensive overall thermal management being installed to ensure survival of the system also in a worst case scenario as requested by ETSI/ANSI.

The existing solutions presents some issues:
1) When a fan failure occurs, the broken fan stops rotating and it is not generating airflow and air pressure anymore. The broken fan becomes an open access towards the environment for the unit airflow system and it is a leakage for the airflow and the pressure generated by the other fans. To meet the ETSI/ANSI requirements, overprovisioned and more expensive thermal management systems must be installed.
2) Increasing the fan power also increases the noise generated by the fans and this is particularly problematic in data centers/server farms.
3) Further, solutions known in the art, like the one disclosed in U.S. Pat. No. 8,120,910 or U.S. Pat. No. 10,813,248 either generate noise by the fins or shutters located in the airflow or are very complex to implement in practice and require significant space around the fan or within the airflow. Disturbing the airflow by any of these known solutions results in noise being generated and this problem is exacerbated in large scale applications like data centers/server farms.

### SUMMARY

According to a first aspect of the present invention there is provided a device for use with a fan. The device comprises a shaft mounted at opposite ends via brackets to a housing of the fan and a curtain for blocking airflow through the fan in a closed position. The curtain being wound onto the shaft in an open position. The device also comprises a closing mechanism for unwinding the curtain to the closed position and a locking mechanism for locking the curtain in the open position. In response to detection of malfunction of the fan the locking mechanism is released and the closing mechanism unwinds the curtain to the closed position.

### BRIEF DESCRIPTION OF THE DRAWINGS

The present invention will be understood and appreciated more fully from the following detailed description taken in conjunction with the drawings in which:

FIG. 1 is a diagram illustrating a fan for cooling electronic equipment with a device for use with the fan in open position in one embodiment of the present invention;

FIG. 2 is a diagram illustrating a fan for cooling electronic equipment with a device for use with the fan in closed position in one embodiment of the present invention;

FIG. 3 is a diagram illustrating a locking mechanism of a device for use with a fan for cooling electronic equipment in one embodiment of the present invention;

FIG. 4 illustrates details of mounting a shaft to a frame of a device for use with a fan for cooling electronic equipment in one embodiment of the present invention;

FIG. 5 illustrates one embodiment of a device for use with a fan for cooling electronic equipment;

FIG. 6 and FIG. 7 illustrate a locking mechanism of a device for use with a fan for cooling electronic equipment in two embodiments of the present invention;

FIG. 8 is a diagram of a control system for thermal management using fans having devices according to embodiments of the present invention.

### DETAILED DESCRIPTION

In the following description, for purposes of explanation and not limitation, specific details are set forth such as particular architectures, interfaces, techniques, etc. in order to provide a thorough understanding of the solution. However, it will be apparent to those skilled in the art that the solution may be practiced in other embodiments that depart from these specific details. In other instances, detailed descriptions of well-known devices, circuits, and methods are omitted so as not to obscure the description of the solution with unnecessary details.

Reference throughout the specification to “one embodiment” or “an embodiment” means that a particular feature, structure, or characteristic described in connection with an embodiment is included in at least one embodiment of the present solution. Thus, the appearance of the phrases “in one embodiment” or “in an embodiment” in various places throughout the specification are not necessarily all referring to the same embodiment. Further, the particular features, structures or characteristics may be combined in any suitable manner in one or more embodiments.

The proposed solution is a low cost device that may be attached to an existing fan, or, alternatively, integrated with a fan module. This device puts a cover (curtain) in front of the fan in the case of a fan failure in order to avoid airflow going through the broken fan into the device to be cooled.

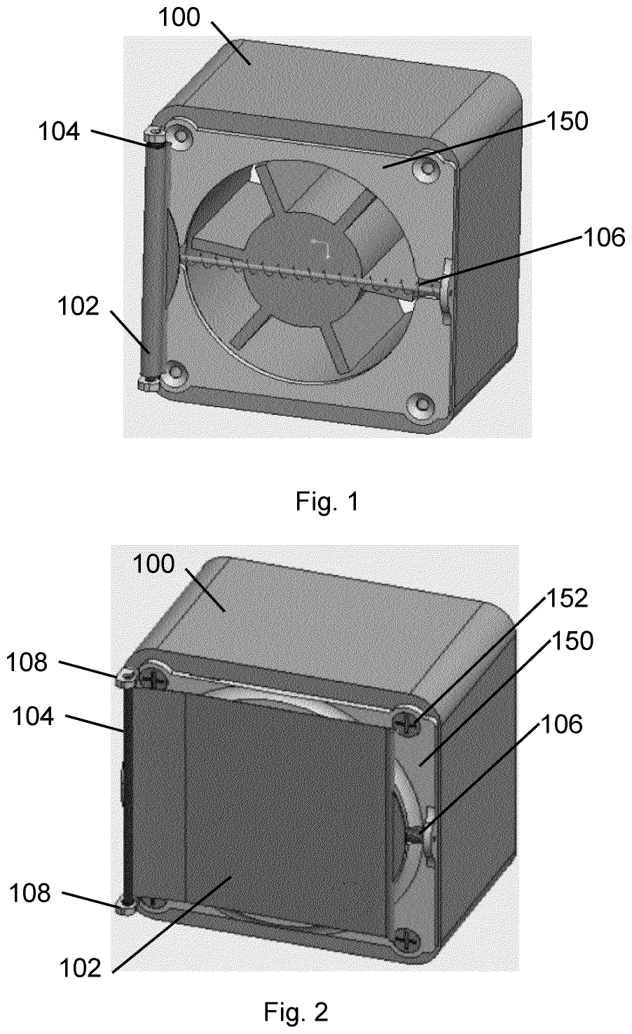

In one embodiment, as illustrated in FIGS. 1 and 2, a device, 150, for use with a fan 100 is now to be described. The device 150 comprises a shaft 104 mounted at opposite ends via brackets 108 to a housing of the fan 100. The device 150 also comprises a curtain, 102, which blocks airflow through the fan in a closed position. The curtain 102 is wound onto the shaft 104 in an open position. In the open position the airflow is not blocked, and air is allowed to pass through the fan 100. The device 100 also comprises a closing mechanism 106 for unwinding the curtain to the closed position and a locking mechanism 302 for locking the curtain in the open position. In operation, in response to detection of a malfunction of the fan 100 (e.g. the fan stops operating) the locking mechanism 302 is released and the closing mechanism unwinds the curtain to the closed position.

Normally, i.e. when the fan is not broken, the curtain 102 (cover) is rolled up on the shaft 104 close to the edge of the fan 100 and in this way it is ensured that during normal operation the fan 100 is able to blow air out of the device that needs to be cooled as shown in FIG. 1.

When the fan breaks, a driver of the fan detects the fault. At this point a control circuit, which may be part of the fan driver or may cooperate with the fan driver, releases the locking mechanism 302, which keeps the curtain in its rolled-up position. Once the cover 102 is released, the elastic force of the closing mechanism 106 unwinds the cover 102 by pulling it across the fan opening and closes it. This stops the leakage of airflow and pressure as is illustrated in one embodiment in FIG. 2.

In one embodiment the locking mechanism comprises a latch which engages with a mating member of the closing mechanism. The latch is fixed to the frame 500 (frame is shown in FIG. 5), whereas the corresponding mating member is fixed to the free end of the curtain 102. When the curtain is in the open position the latch engages with the mating member and locks the curtain in the open position. Preferably the latch is an electromechanical latch controlled by a fan driver or a board controller (both described later in this document).

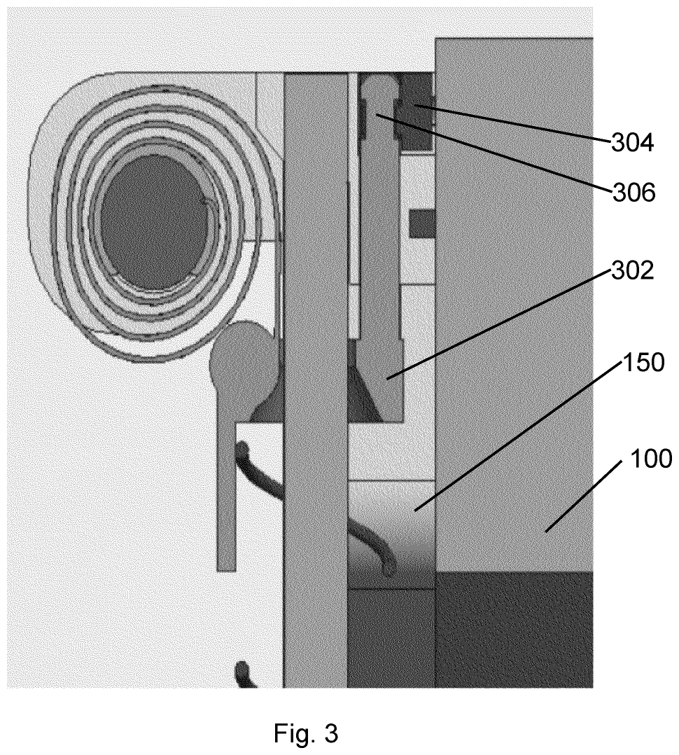

Alternatively, the locking mechanism may comprise an electric resistance element for melting the latch and releasing the curtain to its closed position when connected by the fan driver or board controller to an electric current source in response to detection of malfunction of the fan. In this embodiment, illustrated in FIG. 3 the control circuit, which may be part of the fan driver or may cooperate with the fan driver, releases the locking mechanism 302, which keeps the curtain 102 in its rolled-up position by activating an electrical circuit that starts pumping current into a resistance 304 surrounding a plastic retention pin 306 which keeps the curtain 102 in the open position. After a while the retention pin 306 melts and the locking mechanism 302 releases the curtain. The elastic force of the closing mechanism, e.g., a spring, 106 pulls the cover 102 down in front of the fan and closes the opening formed by the failed fan. In this embodiment the closing mechanism 106 comprises an extension spring 106 having one end attached to the curtain 102 and the other end attached to a fixed element, 106-8, (e.g. a loop in or attached to the frame 500). The closing mechanism, e.g., extension spring, 106 is loaded when the curtain 102 is in the open position (i.e. rolled-up).

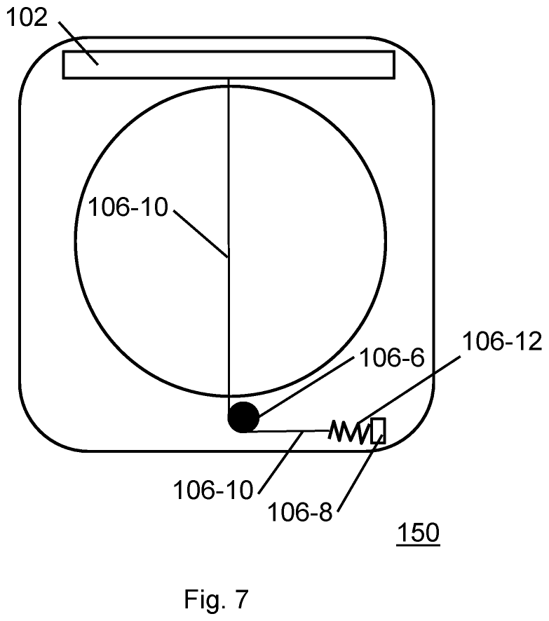

In an alternative embodiment, illustrated in FIG. 7 the closing mechanism 106 comprises an extension spring 106-12 and a cable 106-10. The cable links 106-10 the curtain 102 and one end of the extension spring 106-12 via a guiding element 106-6. The other end of the extension spring is attached to a fixed element 106-8, wherein said extension spring 106-12 is loaded when the curtain 102 is in the open position.

In yet another embodiment the closing mechanism 106 comprises an elastic cable 106-4 having one end attached to the curtain 102 and the other end attached to a fixed element 106-8, wherein said elastic cable 106-4 is loaded when the curtain is in the open position. Preferably the elastic cable 106-4 goes via at least one guiding element 106-6.

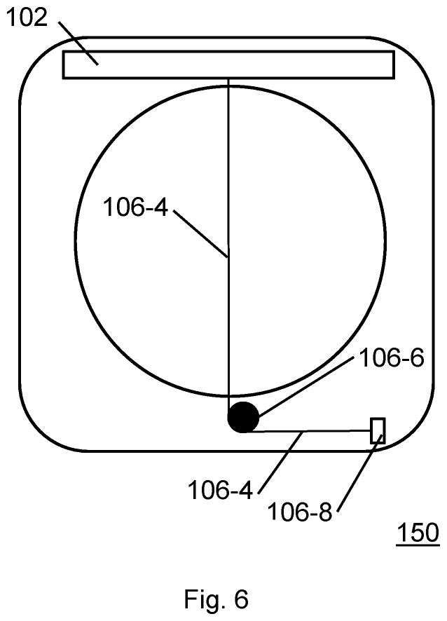

One of the advantages of the solution disclosed in this document is that it is a small device that after installation does not protrude to the sides of the fan, but only occupies the front of the fan. To make this possible for various sizes of the fan, different closing mechanisms may be used. By using a guiding element 106-6 (e.g. a pulley or a loop) it is possible to use the whole length across the fan opening and almost a half of the width of the fan (assuming that the closing mechanism is located centrally). This allows for using a wider selection of elastic cables. If the elastic cable is attached at one end to the curtain 102 and the opposite end to the frame 500 the elastic cable 106-4 is capable of extending several times its free length (i.e. length of the elastic cable when it is not loaded/extended). Alternatively, if the elastic cable 106-4 goes via the guiding element 106-6, as illustrated in FIG. 6, it is possible to use a cable of a lower elasticity because it is possible to use a cable with a greater free length.

In one embodiment the closing mechanism may comprise a cable having one end attached to the curtain and the other attached to a spool, wherein the spool comprises a winding member and the winding member is loaded when the curtain is in the open position. Again, this embodiment allows for keeping the mechanism within the limits defined by the size of the fan and may use a spring-loaded spool. The cable connected to the curtain is wound up on the spool when the curtain is closed and when the curtain is open, the cable is unwound and the spring in the spool is loaded.

This solution is compact and can be applied to existing fans using the same screws 152 that are used to mount the fan 100 to the device to be cooled.

Embodiments of this invention allow for an efficient thermal management in case of failure reducing the number of fans and the total power of fans used to dissipate the same amount oh heat generated by the cooled device. This, in turn, reduces the power consumed by the thermal management module as well as the complexity and cost of the final solution. Further, this allows for reducing the cost of material and the labour needed to build a unit as well as overall power consumption of the equipment unit with evident savings in CAPEX and OPEX for the telecom operator.

The proposed solution is a device that can be applied to existing fans and can be scaled to work with different fan sizes. The device is comprises mechanical parts and an electrical part. The electrical part of this device may be driven by the host board controllers, that detect when the fan is broken and activates electrical part accordingly. First mechanical description of the device is given and than the description of the controlling part.

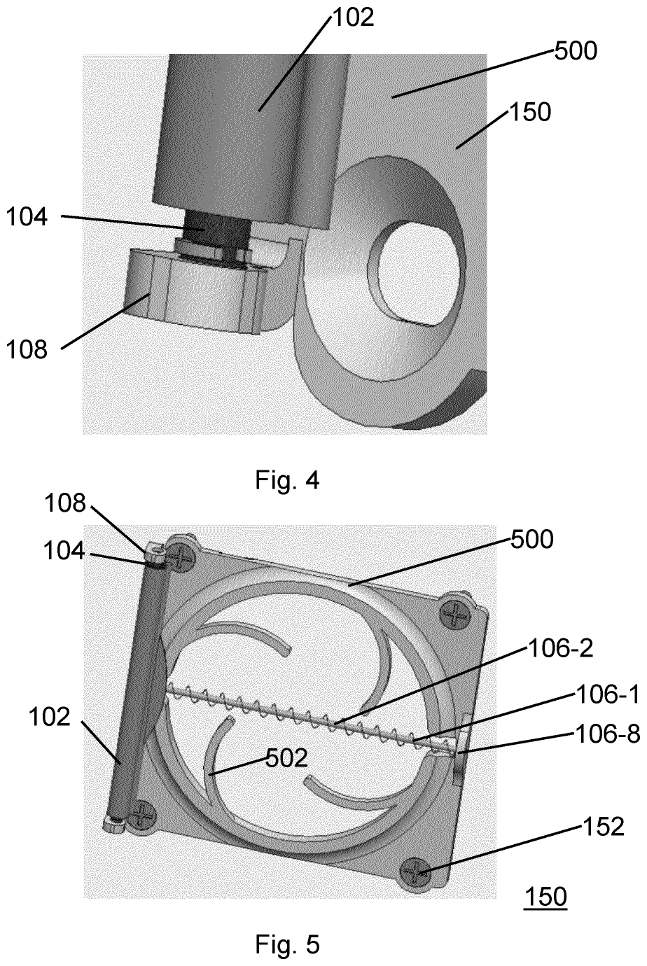

In one embodiment, illustrated in FIGS. 1 and 2, the device 150 is mounted to the fan 100 with four screws 152 at the four corners of the fan according the fan standard. In the embodiment illustrated in FIG. 5 the device 150 comprises a frame, 500, a spring 106-1 and an axis 106-2 forming together the closing mechanism 106, the curtain 102 and the shaft, 104. The curtain 102 is wound around the shaft 104 in the open position and the shaft is rotatably attached to the frame 500 via brackets 108. Further, the device comprises the locking mechanism 302, which in the embodiment illustrated in FIG. 4 is located in proximity of the shaft 104 and comprises a plastic retention pin 306 and an electric resistance 304 configured to melt the plastic retention pin 306.

The frame 500 supports the whole structure, the axis 106-2 with the spring 106-1 and the shaft 104 with the curtain 102 rolled up. In addition the frame 500 supports the electrical resistance 304 and wires (not shown).

In one embodiment the frame may have protrusions 502 in the central opening to improve the cover efficiency once it is in closed position.

Another advantage of the solution is that the device 150 is so compact that can be integrated (retrofitted) inside the current fan tray without modification of the fan tray.

In a preferred embodiment the device 150 is an add-on for attaching to existing fans. However, in an alternative embodiment the device 150 may be integral to the fan. In this embodiment, the brackets 108 are formed at one edge of the fan and on opposite end of the edge. Similarly, the locking mechanism 302 and the closing mechanism 106 may be formed integral with the fan 100 or may be attached directly to the fan.

In a preferred embodiment the locking mechanism 302, after the plastic retention pin 306 is melted down, may be replaced by a new one and the device 150 can be continued to be used after the fan is repaired (in the embodiment with the device 150 formed integrally with the fan 100) or after the faulty fan is replaced (in this embodiment the frame 500 of the device 150 is unscrewed together with the fan and mounted again with a new locking mechanism 302 and a new fan).

The above embodiment is based on melting down a plastic retention pin 306 by a resistor (or electric resistance block). In alternative embodiments an electromagnetic locking mechanism may be used. In this embodiment re-using the device is even more straightforward as no part of the device 150 is damaged in order to close the curtain 102.

In one embodiment the fans are controlled by fan drivers. In short, a fan driver is a control loop that gets target fan speed value from a host controller and according to this target value an error is calculated with respect to the current fan speed. The fan speed information may be obtained from a tachymetric signal coming from the fan. The fan driver also modulates the fan control signal PWM (pulse width modulation) in order to reduce the calculated error.

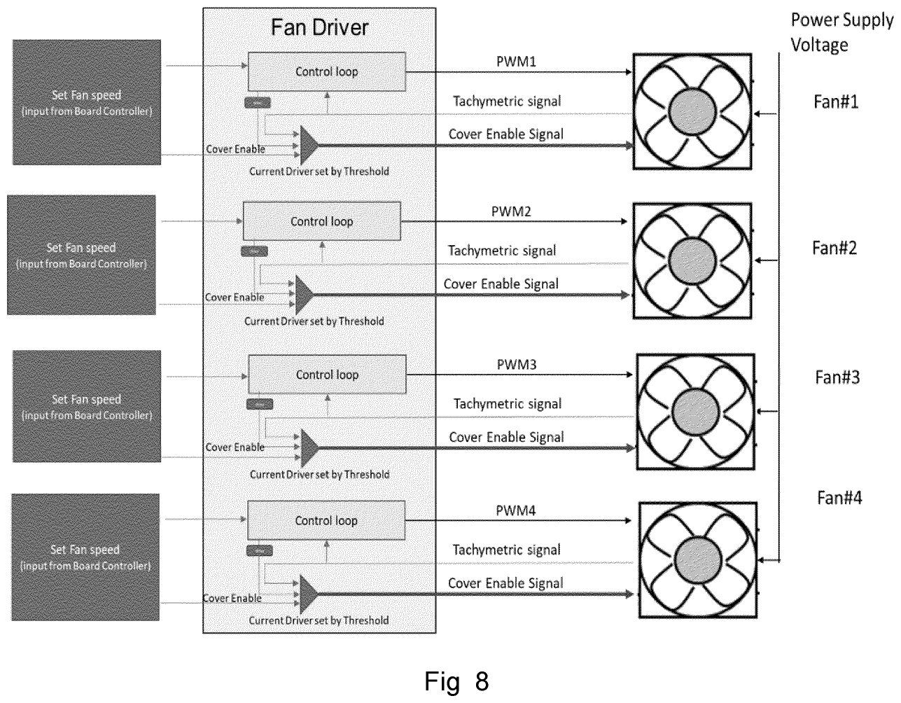

Once a fan breaks the tachymetric signal, that reports the information of the fan speed, drops to zero. In this case the control loop raises an alarm indicating that the fan is out of control (broken). This alarm may be used both internally at the fan driver and may be reported to the board controller together with the tachymetric signal report. A signal activating closing of the curtain 102 (curtain enable signal) may be generated by the fan driver (after a proper delay and with some hysteresis on the tachymetric signal) or by the board controller. Once the curtain enable signal is activated the electric resistance 304 of the device 150 is driven and current start flowing into it. After a while the plastic retention pin 306 is melted and breaks, and the cover/curtain 102 is released. A diagram of a control system operating according to the above described embodiment is illustrated in FIG. 8.

It should be noted that the above-mentioned examples illustrate rather than limit the disclosure, and that those skilled in the art will be able to design many alternative embodiments without departing from the disclosed solution. The word “comprising” does not exclude the presence of elements or steps other than those listed, “a” or “an” does not exclude a plurality.

1. A device for use with a fan, the device comprising:
a shaft mounted at opposite ends via brackets to a housing of the fan;
a curtain for blocking airflow through the fan in a closed position, the curtain being wound onto the shaft in an open position;
a closing mechanism for unwinding the curtain to the closed position; and
a locking mechanism for locking the curtain in the open position; and
in response to detection of malfunction of the fan the locking mechanism is released and the closing mechanism unwinds the curtain to the closed position.

2. The device according to claim 1, further comprising a frame having the brackets, the frame being attachable to a housing of the fan.

3. The device according to claim 1, wherein the closing mechanism comprises an extension spring having one end attached to the curtain and the other end attached to a fixed element, the extension spring being loaded when the curtain is in open position.

4. The device according to claim 1, wherein the closing mechanism comprises an extension spring and a cable linking, via a guiding element, the curtain and one end of the extension spring, wherein the other end of the extension spring is attached to a fixed element, the extension spring being loaded when the curtain is in the open position.

5. The device according to claim 1, wherein the closing mechanism comprises an elastic cable having one end attached to the curtain and the other end attached to a fixed element, the elastic cable being loaded when the curtain is in the open position.

6. The device according to claim 5, wherein the elastic cable goes via at least one guiding element.

7. The device according to claim 1, wherein the closing mechanism comprises a cable having one end attached to the curtain and the other attached to a spool, wherein the spool comprises a winding member and the winding member is loaded when the curtain is in open position.

8. The device according to claim 4, wherein the guiding element comprises a pulley.

9. The device according to claim 1, wherein the locking mechanism comprises a latch which engages with a mating member of the closing mechanism at the free end of the curtain when the curtain is in the open position and locks the curtain in the open position.

10. The device according to claim 9, wherein the locking mechanism comprises electric resistance element, the electric resistance element being operative to increase its temperature when connected to an electric current source in response to detection of malfunction of the fan and melt the latch.

11. The device according to claim 9, wherein the latch comprises an electromechanical latch.

12. The device according to claim 2, wherein the closing mechanism comprises an extension spring having one end attached to the curtain and the other end attached to a fixed element, the extension spring being loaded when the curtain is in open position.

13. The device according to claim 2, wherein the closing mechanism comprises an extension spring and a cable linking, via a guiding element, the curtain and one end of the extension spring, wherein the other end of the extension spring is attached to a fixed element, the extension spring being loaded when the curtain is in the open position.

14. The device according to claim 2, wherein the closing mechanism comprises an elastic cable having one end attached to the curtain and the other end attached to a fixed element, the elastic cable being loaded when the curtain is in the open position.

15. The device according to claim 14, wherein the elastic cable goes via at least one guiding element.

16. The device according to claim 2, wherein the closing mechanism comprises a cable having one end attached to the curtain and the other attached to a spool, wherein the spool comprises a winding member and the winding member is loaded when the curtain is in open position.

17. The device according to claim 2, wherein the locking mechanism comprises a latch which engages with a mating member of the closing mechanism at the free end of the curtain when the curtain is in the open position and locks the curtain in the open position.

18. The device according to claim 17, wherein the locking mechanism comprises electric resistance element, the electric resistance element being operative to increase its temperature when connected to an electric current source in response to detection of malfunction of the fan and melt the latch.

19. The device according to claim 17, wherein the latch comprises an electromechanical latch.

20. The device according to claim 3, wherein the locking mechanism comprises a latch which engages with a mating member of the closing mechanism at the free end of the curtain when the curtain is in the open position and locks the curtain in the open position.
